(19) United States
(12) Patent Application Publication
(10) Pub. No.: US 2022/0229286 A1
(43) Pub. Date: Jul. 21, 2022

(54) MEMS DEVICE AND OPTICAL DEVICE

(71) Applicant: Coretronic Corporation, Hsin-Chu (TW)

(72) Inventor: Chih-Hsien Tsai, Hsin-Chu (TW)

(73) Assignee: Coretronic Corporation, Hsin-Chu (TW)

(21) Appl. No.: 17/525,969

(22) Filed: Nov. 15, 2021

(30) Foreign Application Priority Data
Jan. 15, 2021 (CN) 202110052967.4

(51) Int. Cl. G02B 26/08; G02B 26/10

(52) U.S. Cl. CPC G02B 26/0833; G02B 26/105

(57) ABSTRACT

A MEMS device including a plurality of reflective elements, at least one movable frame, a fixed frame, and a controller is provided. The reflective elements are respectively coupled to the movable frame by a plurality of fast pivots, and the fixed frame is coupled to the at least one movable frame by a slow pivot. A swing frequency of the slow pivot is less than a swing frequency of each of the fast pivots. The controller is coupled to the fixed frame and selectively controls a swing of the reflective elements with the fast pivots and the slow pivot as a swing pivot. A first reflective element and a second reflective element in the reflective elements are respectively used to reflect a first beam and a second beam, to respectively form a first reflective beam and a second reflective beam.

### CROSS-REFERENCE TO RELATED APPLICATION

This application claims the priority benefit of China application serial no. 202110052967.4, filed on Jan. 15, 2021. The entirety of the above-mentioned patent application is hereby incorporated by reference herein and made a part of this specification.

### BACKGROUND

### Technical Field

The disclosure relates to a MEMS device and an optical device including the MEMS device.

### Description of Related Art

Micro-electromechanical system (MEMS) devices are widely used in various fields. For example, they may be applied to products such as a scanning projector or a LiDAR, etc. The existing MEMS will be designed to drive the pivots to rotate in the X and Y pivot directions according to the requirements for the swing type, so that the lens swings in one-dimensional or two-dimensional. However, taking the MEMS device applied to the scanning display system as an example, since the load of the general pivot has its limit, if the resolution is to be further improved, the usual method is to use a high-specification pivot. However, this method has resulted in low R&D and commercial benefits.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY

The disclosure provides a MEMS device, which enables an optical device using the MEMS device to have a higher resolution at a lower cost and a longer service life.

The disclosure provides an optical device, which may have a better optical effect at a lower cost and has a longer service life.

Other objects and advantages of the disclosure may be further understood from the technical features disclosed herein.

An embodiment of the disclosure provides a MEMS device including multiple reflective elements, at least one movable frame, a fixed frame, and a controller. The movable frame has multiple fast pivots. The reflective elements are respectively coupled to the movable frame by the fast pivots. The fixed frame has a slow pivot. The at least one movable frame is disposed in the fixed frame, and the fixed frame is coupled to the at least one movable frame by the slow pivot. A swing frequency of the slow pivot is less than a swing frequency of each of the fast pivots, and an axial direction of the slow pivot is different from an axial direction of the fast pivot. The controller is coupled to the fixed frame and selectively controls the swing of the reflective elements with the fast pivots and the slow pivot as a swing pivot. A first reflective element and a second reflective element in the reflective elements are respectively used to reflect a first beam and a second beam, to respectively form a first reflective beam and a second reflective beam.

An embodiment of the disclosure provides an optical device including at least one light source and the MEMP device. The light source is used to provide a beam. The reflective element is disposed on a transmission path of the beam.

Based on the above, in the MEMS device and the optical device of the embodiment of the disclosure, the reflective elements are coupled to the movable frame by the fast pivots. Therefore, the load of each of the fast pivots may be reduced, and the maximum operating frequency of the fast pivot may be increased, so that the optical device using the MEMS device may have a good optical effect and service life.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic block diagram of an optical device and a projection medium according to an embodiment of the disclosure.

FIG. 2 is a schematic diagram of an appearance of a MEMS device of the optical device in FIG. 1.

FIGS. 3A and 3B respectively show MEMS devices having reflective elements with different initial offset conditions.

FIG. 4 is a schematic diagram of an optical path of the MEMS device of FIG. 3A.

FIGS. 5 and 6 are schematic diagrams of optical devices according to different embodiments of the disclosure.

FIG. 7 is a schematic diagram of an appearance of a MEMS device according to another embodiment of the disclosure.

### DETAILED DESCRIPTION OF DISCLOSED EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

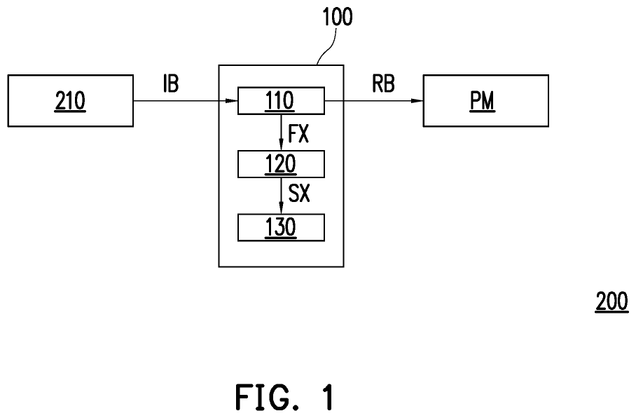

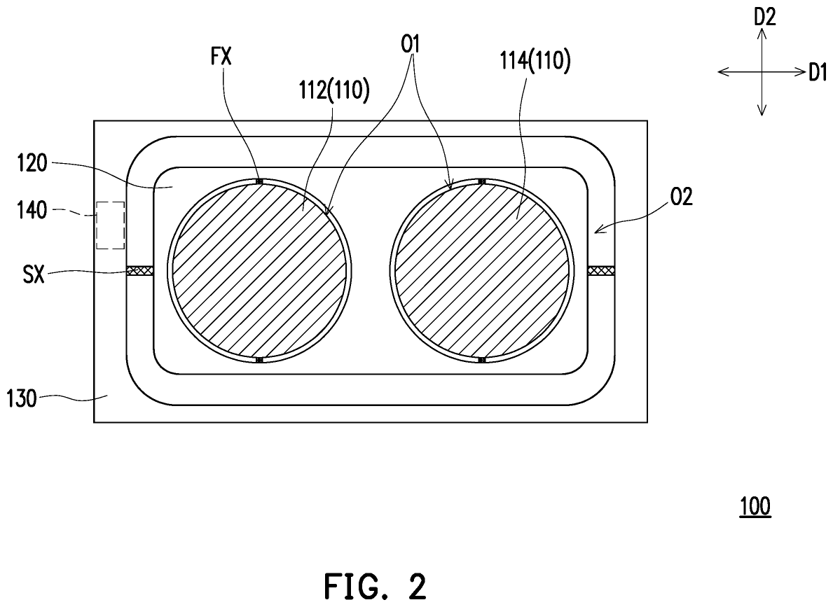

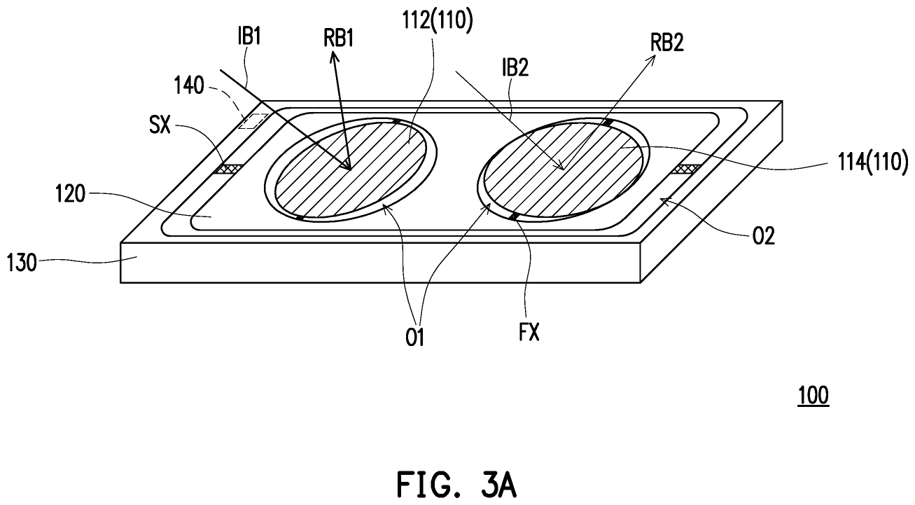

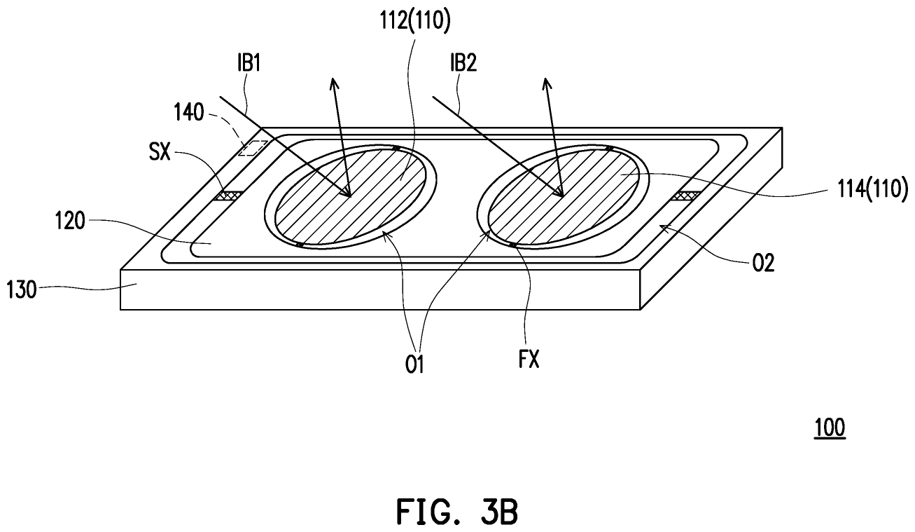

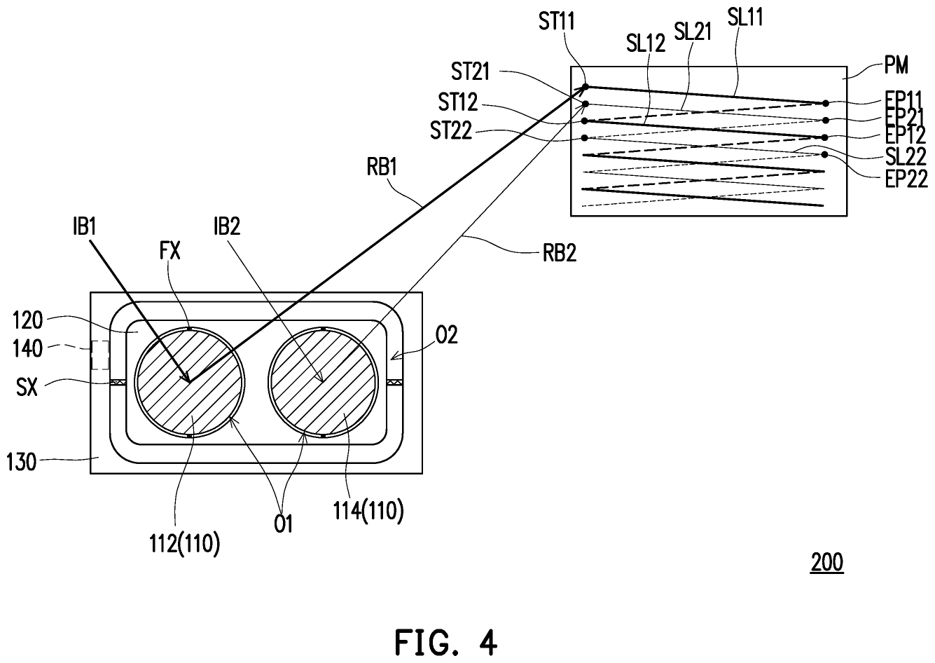

FIG. 1 is a schematic block diagram of an optical device and a projection medium according to an embodiment of the disclosure. FIG. 2 is a schematic diagram of an appearance of a MEMS device of the optical device in FIG. 1. FIGS. 3A and 3B respectively show MEMS devices having reflective elements with different initial offset conditions. FIG. 4 is a schematic diagram of an optical path of the MEMS device of FIG. 3A.

Referring to FIGS. 1 and 2, in this embodiment, an optical device 200 includes at least one light source 210 and a MEMS device 100. For example, the optical device 200 may be a projection device, a LiDAR, or other suitable optical devices including the MEMS device 100, and the disclosure is not limited thereto. For simplicity's sake, the optical device 200 takes the projection device as an example, and the MEMS device 100 is, for example, a light valve applied to the projection device, but is not limited thereto.

The light source 210 includes a light emitting element that may emit a beam (illumination beam), or, the light source 210 also includes an optical element assembly composed of various optical elements with different optical functions, and the disclosure is not limited thereto. The light source 210 is used to provide a beam IB. In this embodiment, the number of the light source 210 is, for example, one, but is not limited thereto. The light emitting element is, for example, a laser light source.

The MEMS device 100 includes multiple reflective elements 110, at least one movable frame 120, a fixed frame 130, and a controller 140 (as shown in FIG. 2). The controller 140 may be disposed on the fixed frame 130.

The reflective element 110 is, for example, an optical element with a reflective function, which is, for example, a mirror coated with a high-reflectivity substance. The high-reflectivity substance is, for example, a metal, but is not limited thereto. In this embodiment, the number of the reflective element 110 is, for example, two, but is not limited thereto, and the two reflective elements 110 are respectively called a first reflective element 112 and a second reflective element 114. The reflective elements 110 are disposed on a transmission path of the beam IB.

The movable frame 120 has multiple openings O1, and the movable frame 120 has multiple fast pivots FX. The reflective elements 110 are respectively disposed on the openings O1 (or disposed on the openings O1 one by one), and the reflective elements 110 are respectively coupled to the movable frame 120 by the fast pivots FX. An axial direction of each of the fast pivots FX is, for example, in a direction D2, and a swing frequency (e.g., during enable period) of each of the fast pivots falls within a range of 27 kilohertz (kHz) to 54 kilohertz (kHz), but is not limited thereto. In this embodiment, the number of the movable frame 120 is, for example, one, but is not limited thereto.

The fixed frame 130 has an opening O2, and the fixed frame 130 has a slow pivot SX. The movable frame 120 is disposed in the opening O2 and is coupled to the fixed frame 130 by the slow pivot SX. An axial direction of the slow pivot SX is, for example, in a direction D1, and a swing frequency of the slow pivot is, for example, 60 kilohertz (kHz), but is not limited thereto. Moreover, the direction D1 and the direction D2 are perpendicular to each other.

In other words, the swing frequency of the slow pivot SX is less than the swing frequency of each of the fast pivots FX. The axial direction of the slow pivot SX is different from the axial direction of the fast pivot FX, and for example, the axial direction of the slow pivot SX and the axial direction of the fast pivot FX are perpendicular to each other, but is not limited thereto. In other embodiments, the axial direction of the slow pivot SX may also be inclined by an angle opposite to the axial direction of the fast pivot FX, but is not limited thereto.

In more detail, the fixed frame 130 has a first driving device (not shown). With the slow pivot SX as a swing pivot (swing axis), the movable frame 120 is driven to swing opposite to the fixed frame 130. The movable frame 120 has a second driving device (not shown). With the fast pivot FX as the swing pivot, the reflective element 110 is driven to swing opposite to the movable frame 120. The driving device belongs to micro-electromechanical systems (MEMS), for example, an electromagnetic device, an electrostatic device, or a piezoelectric device, etc., but is not limited thereto. Any micro-electromechanical system that may be used by those skilled in the art may be used in the disclosure.

The controller 140 is connected to the driving device, so as to control actuations of the fast pivots FX and the slow pivot SX. The controller 140 may control the reflective element 110 to swing back and forth relative to the movable frame 120 in the direction D1 with the fast pivot FX as the swing pivot, and the controller 140 may control the movable frame 120 to swing back and forth relative to the fixed frame 130 in the direction D2 with the slow pivot SX as the swing pivot. The controller 140 is, for example, a central processing unit (CPU), or other programmable general-purpose or special-purpose microprocessors, a programmable controller, application specific integrated circuits (ASICs), a programmable logic device (PLD), other similar devices, or a combination of these devices.

Hereinafter, the technical effect of the optical device 200 in this embodiment will be described in detail.

Referring to FIGS. 1, 2, 3A and 3B, the light source 210 emits the beam IB. The beam IB at least includes a first beam IB1 and a second beam IB2. The first beam IB1 of the beam IB is transmitted to the first reflective element 112 and is reflected by the first reflective element 112 to form a first reflective beam RB1, and the second beam IB2 of the beam IB is transmitted to the second reflective element 114 and is reflected by the second reflective element 114 to form the second reflective beam RB2. A reflective beam RB includes the first reflective beam RB1 and the second reflective beam RB2. The reflective beam RB is transmitted to a projection medium PM. In this embodiment, the first and the second beams IB1 and IB2 are from the same light source 210. In an embodiment, the beam IB may be split into the first and the second beams IB1 and IB2 by a beam splitter (not shown), so as to guide the first and the second beams IB1 and IB2 to the first and the second reflective elements 112 and 114. In another embodiment, instead of splitting the beam by the beam splitter, the beam IB may directly illuminate the first and the second reflective elements 112 and 114. The disclosure is not limited thereto.

Referring to FIG. 3A, in an embodiment, the controller 140 is used to control the swing condition (e.g., initial state, swing frequency) of the reflective elements 110, and multiple initial offset angles of the reflective elements 110 opposite to the movable frame 120 are different from one another. In detail, the controller 140 is used to send multiple control signals to the driving device. A signal form of the control signal is, for example, a sine wave form, which is, for example, a sine wave or a cosine wave. The controller 140 may set phases of the control signals to be different from one another. Therefore, the initial offset angles are different from one another. In this way, the reflective elements may guide the first and the second reflective beams RB1 and RB2 out of the MEMS device 100 at different emission angles.

Referring to FIG. 3B, in another embodiment, the controller 140 is used to control the swing condition of the reflective elements 110, and multiple initial offset angles of the reflective elements 110 opposite to the movable frame 120 are the same as one another. The controller 140 may set phases of the control signals to be the same as one another. Therefore, the initial offset angles are the same as one another. In this way, the reflective elements may guide the first and the second reflective beams RB1 and RB2 out of the MEMS device 100 at the same emission angles.

In view of the above, in the MEMS device 100 and the optical device 200 of this embodiment, the reflective elements 110 are coupled to the movable frame 120 by the fast pivots FX. Assuming that those skilled in the art plan to design a total area of reflective surfaces of the reflective elements 110 of the MEMS device 100, the torsion required for each of the fast pivots FX is represented by (the total area)/(the number of the reflective element 110). Therefore, the more fast pivots FX are designed, the workload of each of the fast pivots FX may be reduced, so the maximum operating frequency and the service life of each of the fast pivots FX may be improved.

Referring to FIGS. 3A and 4, in the embodiment of FIG. 3A, when the first and the second reflective beams RB1 and RB2 are emitted at different emission angles, the first and the second reflective beams RB1 and RB2 will illuminate on different positions of a projection medium PM (such as a projection screen, a wall, or eyes, but is not limited thereto). The first reflective beam RB1 illuminates along a first scanning path SL11, and the second reflective beam RB2 illuminates along a second scanning path SL21. The first scanning path SL11 and the second scanning path SL21 are different from each other, which is, for example, are parallel to each other.

Next, when the first and the second reflective beams RB1 and RB2 respectively illuminate endpoints EP11 and EP21 of the first scanning path SL11 and the second scanning path SL21, the controller 140 controls the movable frame 120 to rotate at a certain angle. In this process, the first reflective beam RB1 moves from the endpoint EP11 of the first scanning path SL11 to a start point ST12 of a next first scanning path SL12 (that is, the dotted part). Similarly, the second reflective beam RB2 moves from the endpoint EP21 of the second scanning path SL21 to a start point ST22 of a next second scanning path SL22 (that is, the dotted part). The second scanning path SL21 is located between the first scanning path SL11 and the next first scanning path SL12.

After the optical device 200 performs the above steps one or more times, an image may be scanned.

In addition, in this embodiment, the controller 140 is used to control a phase difference between the two control signals of the first and the second reflective elements, for example, 180 degrees, compared to the phase difference of 90 degrees or 270 degrees. When the phase difference between the two control signals is 180 degrees, the scanned image has a good resolution.

In view of the above, compared to the known technology that uses a high-specification fast pivot to drive the reflective element to achieve a high resolution, in the MEMS device 100 and the optical device 200 of this embodiment, due to the configuration of the reflective elements 110 (initial offset angles are different), the beam IB may be reflected to different positions by the reflective elements 110, and the controller 140 then controls the reflective element 110 to scan a reflective beam reflected by the reflective element 110 in different scanning paths In this way, this embodiment may achieve a high resolution effect with a lower swing frequency.

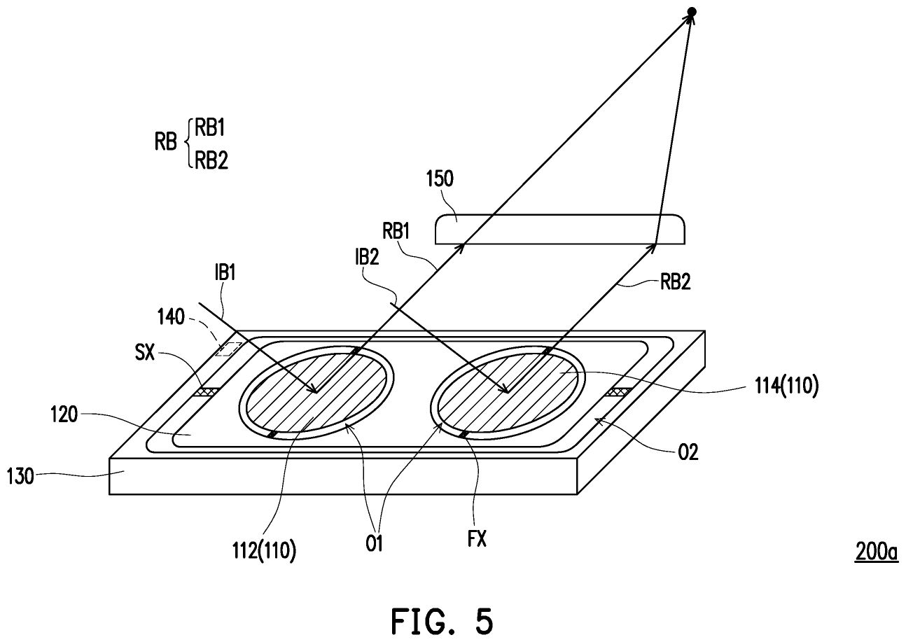

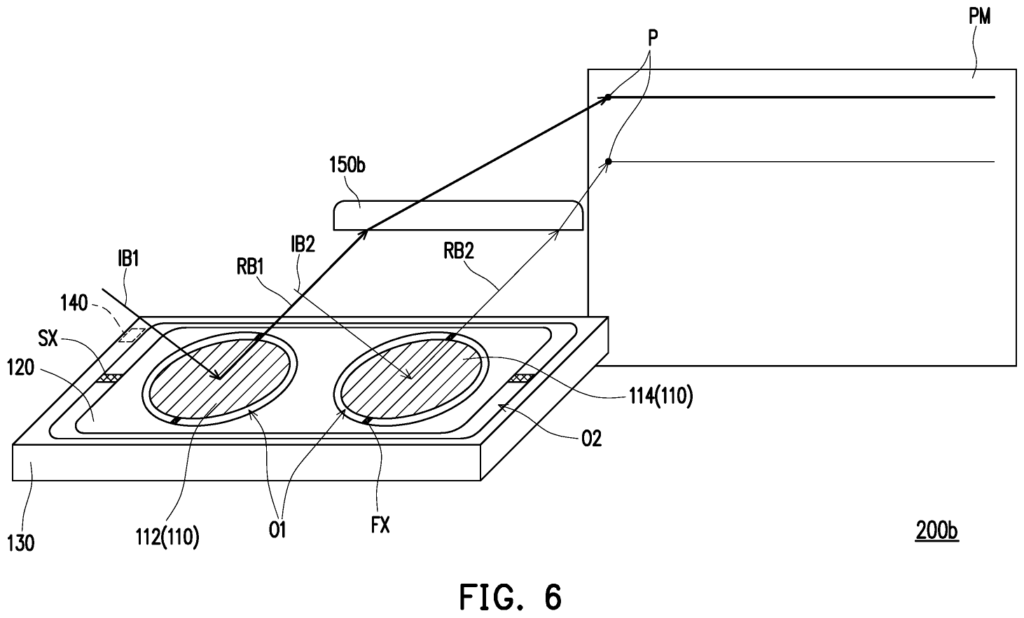

FIGS. 5 and 6 are schematic diagrams of optical devices according to different embodiments of the disclosure.

An optical device 200a of the embodiment of FIG. 5 is substantially similar to the optical device 200 of FIGS. 1 and 4, and the main difference is that the optical device 200a also includes an optical path adjustment element 150. In this embodiment, the optical path adjustment element 150 is, for example, an F-theta lens, which is disposed on transmission paths of reflective beams RB. The optical path adjustment element 150 may converge the reflective beams RB1 and RB2 at one point. Therefore, the brightness of the image scanned by the optical device 200a may be further improved.

An optical device 200b of the embodiment of FIG. 6 is substantially similar to the optical device 200a of FIG. 5, and the main difference is that the optical device 200b also adopts an optical path adjustment element 150b with different optical effect. In this embodiment, the optical path adjustment element 150b is, for example, a liquid crystal lens or an F-theta lens, but is not limited thereto. The optical path adjustment element 150b may adjust the optical paths of the reflective beams RB (RB1 and RB2) to illuminate on multiple aligned positions P of the projection medium PM. Therefore, the brightness of the image scanned by the optical device 200b may be further improved.

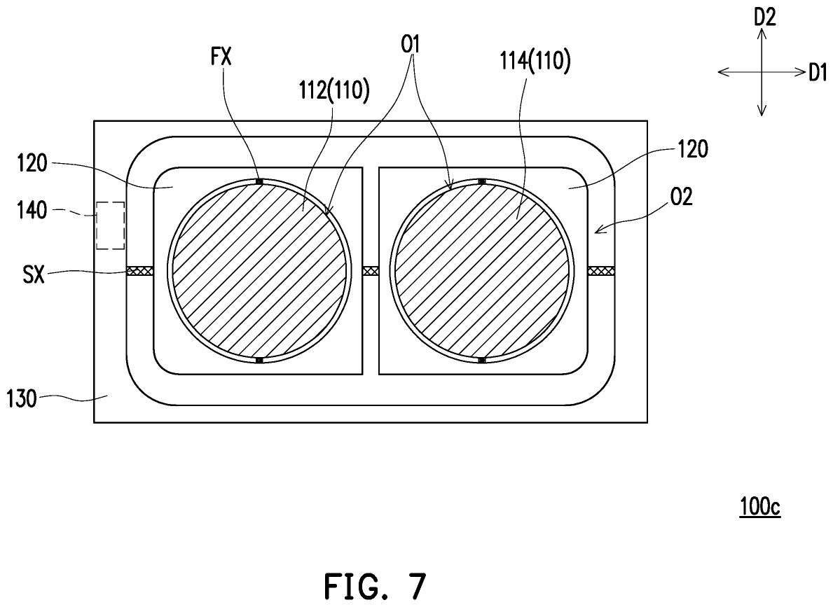

FIG. 7 is a schematic diagram of an appearance of a MEMS device according to another embodiment of the disclosure.

A MEMS device 100c of the embodiment of FIG. 7 is substantially similar to the MEMS device 100 of FIG. 2, and the main difference is that the number of movable frames 120 of the MEMS device 100c is plural, and two are taken as an example in this embodiment. The slow pivot SX is used to connect the movable frame 120 and the fixed frame 130, and the slow pivot SX is used to connect the movable frames 120. With this configuration, the controller 140 of the MEMS device 100c may control the movable frames 120 to have different swing methods based on the actuation of the slow pivot SX (with the slow pivot SX as the swing pivot), so the reflective beam RB may have various scanning paths, which may implement different applications.

It should be noted that, in the above embodiment, the number of the reflective element is two, so the number of the reflected reflective beam is also two. However, in other embodiments, those of ordinary skill in the art may adjust the number of the reflective element according to the cost and the degree of difficulty in manufacturing, for example, a number greater than two, thereby adjusting the number of the scanning path to further improve the resolution.

In addition, in the above embodiment, the number of light sources is one, and the first and the second beams are from the same light source. However, in other embodiments, the number of the light source may be changed to plural. The first beam is emitted by one of the light sources, and the second beam is emitted by another one of the light sources. In other words, the first and the second beams may be emitted by the independent light sources, and the disclosure is not limited thereto.

Based on the above, in the MEMS device and the optical device of the embodiment of the disclosure, the reflective elements are coupled to the movable frame by the fast pivots. Therefore, the workload of each of the fast pivots may be reduced, and the maximum operating frequency of the fast pivot may be increased, thereby improving the resolution of the scanned image. Moreover, because the workload of the fast pivot is reduced, the service life of the MEMS device and the optical device may also be increased. In addition, the controller may control the reflective element to scan the reflective beam reflected by the reflective element in different scanning paths with the fast pivot and the slow pivot as the swing pivot. The various different scanning paths are more helpful to improve the resolution of the image.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A micro-electromechanical system (MEMS) device, comprising a plurality of reflective elements, at least one movable frame, a fixed frame, and a controller, wherein:
the at least one movable frame has a plurality of fast pivots, and the plurality of reflective elements are respectively coupled to the movable frame by the plurality of fast pivots;
the fixed frame has a slow pivot, the at least one movable frame is disposed in the fixed frame, and the fixed frame is coupled to the at least one movable frame by the slow pivot, wherein a swing frequency of the slow pivot is less than a swing frequency of each of the fast pivots, and an axial direction of the slow pivot is different from an axial direction of the plurality of fast pivot; and
the controller is coupled to the fixed frame, and selectively controls a swing condition of the plurality of reflective elements with the plurality of fast pivots and the slow pivot as a swing pivot, wherein a first reflective element and a second reflective element in the plurality of reflective elements are respectively used to reflect a first beam and a second beam, to respectively form a first reflective beam and a second reflective beam.

2. The MEMS device according to claim 1, wherein the controller is used to control the swing condition of the plurality of reflective elements, so that a plurality of initial offset angles of the plurality of reflective elements respectively relative to the movable frame are the same as one another.

3. The MEMS device according to claim 1, wherein the controller is used to control the swing condition of the plurality of reflective elements, so that a plurality of initial offset angles of the plurality of reflective elements respectively relative to the movable frame are different from one another.

4. The MEMS device according to claim 3, wherein
the controller is used to control the first reflective element, so that the first reflective beam illuminates along a first scanning path,
the controller is used to control the second reflective element, so that the second reflective beam illuminates along a second scanning path,
wherein the first scanning path is different from the second scanning path.

5. The MEMS device according to claim 4, wherein
the controller is used to control the plurality of reflective elements, so that the first reflective beam moves from an endpoint of the first scanning path to a start point of a next first scanning path, and the second reflective beam moves from an endpoint of the second scanning path to a start point of a next second scanning path,
wherein the second scanning path is located between the first scanning path and the next first scanning path.

6. The MEMS device according to claim 3, wherein
the controller is used to send a plurality of control signals, wherein a phase difference of the plurality of control signals is different from one another, so that the plurality of initial offset angles are different from one another.

7. The MEMS device according to claim 1, wherein the number of the at least one movable frame is one, the movable frame has a plurality of openings, and the plurality of reflective elements are respectively disposed on the plurality of openings.

8. The MEMS device according to claim 1, wherein the number of the at least one movable frame is plural, each of the movable frames has an opening, and the plurality of reflective elements are respectively disposed on the plurality of openings.

9. The MEMS device according to claim 1, wherein the axial direction of the slow pivot and the axial direction of the plurality of fast pivot are perpendicular to each other.

10. An optical device, comprising at least one light source and a MEMS device, wherein:
the at least one light source is used to provide a beam; and
the MEMS device comprises a plurality of reflective elements, at least one movable frame, a fixed frame, and a controller, wherein:
the plurality of reflective elements are disposed on a transmission path of the beam;
the at least one movable frame has a plurality of fast pivots, and the reflective elements are respectively coupled to the movable frame by plurality of the fast pivots;
the fixed frame has a slow pivot, the at least one movable frame is disposed in the fixed frame, and the fixed frame is coupled to the at least one movable frame by the slow pivot, wherein a swing frequency of the slow pivot is less than a swing frequency of each of the fast pivots, and an axial direction of the slow pivot is different from an axial direction of the plurality of fast pivot; and
the controller is coupled to the fixed frame, and selectively controls a swing condition of the plurality of reflective elements with the plurality of fast pivots and the slow pivot as a swing pivot, wherein a first reflective element and a second reflective element in the plurality of reflective elements are respectively used to reflect a first beam and a second beam from the at least one light source, to respectively form a first reflective beam and a second reflective beam.

11. The optical device according to claim 10, wherein the controller is used to control the swing condition of the plurality of reflective elements, so that a plurality of initial offset angles of the reflective elements respectively relative to the movable frame are the same as one another.

12. The optical device according to claim 10, wherein the controller is used to control the swing condition of the plurality of reflective elements, so that a plurality of initial offset angles of the plurality of reflective elements respectively relative to the movable frame are different from one another.

13. The optical device according to claim 12, wherein the controller is used to control the first reflective element, so that the first reflective beam illuminates along a first scanning path, and the controller controls the second reflective element, so that the second reflective beam illuminates along a second scanning path, wherein the first scanning path is different from the second scanning path.

14. The optical device according to claim 13, wherein
the controller controls the plurality of reflective elements, so that the first reflective beam moves from an endpoint of the first scanning path to a start point of a next first scanning path, and the second reflective beam moves from an endpoint of the second scanning path to a start point of a next second scanning path,
wherein the second scanning path is located between the first scanning path and the next first scanning path.

15. The optical device according to claim 13, wherein the number of the at least one light source is one, and the first beam and the second beam are from the light source.

16. The optical device according to claim 13, wherein the number of the at least one light source is plural, the first beam is emitted by one of the plurality of light sources, and the second beam is emitted by another one of the plurality of light sources.

17. The optical device according to claim 10, wherein the number of the at least one movable frame is one, and the movable frame has a plurality of openings, and the plurality of reflective elements are respectively disposed on the plurality of openings.

18. The optical device according to claim 10, wherein the number of the at least one movable frame is plural, and each of the movable frames has an opening, the plurality of reflective elements are respectively disposed on the plurality of openings, and the slow pivot is used to connect the plurality of movable frames.

19. The optical device according to claim 10, further comprising an optical path adjustment element, wherein when the beam is transmitted to the plurality of reflective elements, the beam is reflected by the plurality of reflective elements to form a plurality of reflective beams, and the optical path adjustment element is disposed on a transmission path of the plurality of reflective beams, wherein the optical path adjustment element is used to converge the plurality of reflective beams.

20. The optical device according to claim 10, further comprising an optical path adjustment element, wherein when the beam is transmitted to the plurality of reflective elements, the beam is reflected by the plurality of reflective elements to form a plurality of reflective beams, and the optical path adjustment element is disposed on a transmission path of the plurality of reflective beams, wherein the optical path adjustment element is used to illuminate the plurality of reflective beams to a plurality of aligned positions on a projection medium.
